(19) United States
(12) Patent Application Publication
(10) Pub. No.: US 2017/0148823 A1
(43) Pub. Date: May 25, 2017

(54) WIRE GRID POLARIZER AND DISPLAY DEVICE INCLUDING THE SAME

(71) Applicant: SAMSUNG DISPLAY CO., LTD., Yongin-si (KR)

(72) Inventors: Jung Gun NAM, Suwon-si (KR); Kyung Seop KIM, Hwaseong-si (KR); Dae Young LEE, Seoul (KR); Gug Rae JO, Asan-si (KR)

(21) Appl. No.: 15/358,460

(22) Filed: Nov. 22, 2016

(30) Foreign Application Priority Data
Nov. 25, 2015 (KR) 10-2015-0165264

(51) Int. Cl. H01L 27/12; G02B 5/30

(52) U.S. Cl. CPC H01L 27/1218; H01L 27/124; G02B 5/3058; G02F 1/133528

(57) ABSTRACT

A wire grid polarizer includes a substrate, and a plurality of wire grid patterns arranged on the substrate at regular intervals, each of the wire grid patterns including a plurality of metal patterns in a stack on the substrate with an intermediate pattern interleaved between adjacent metal patterns in the stack.

### CROSS-REFERENCE TO RELATED APPLICATION

Korean Patent Application No. 10-2015-0165264, filed on Nov. 25, 2015, in the Korean Intellectual Property Office, and entitled: “Wire Grid Polarizer and Display Device Including the Same,” is incorporated by reference herein in its entirety.

### BACKGROUND

1. Field

Embodiments relate to a wire grid polarizer and a display device including the same.

2. Description of the Related Art

A polarizer, which controls the polarization state of light, is widely used in display devices such as liquid crystal displays (LCDs). The polarizer may convert natural light into light with a single linear polarization.

### SUMMARY

Embodiments are directed to a wire grid polarizer, including a substrate, and a plurality of wire grid patterns arranged on the substrate at regular intervals, each of the wire grid patterns including a plurality of metal patterns in a stack on the substrate with an intermediate pattern interleaved between adjacent metal patterns in the stack.

Each of the wire grid patterns may include a first metal pattern which is disposed on the substrate, a first intermediate pattern which is disposed on the first metal pattern, a second metal pattern which is disposed on the first intermediate pattern and whose grain growth is controlled by the first intermediate pattern, a second intermediate pattern which is disposed on the second metal pattern, a third metal pattern which is disposed on the second intermediate pattern and whose grain growth is controlled by the second intermediate pattern, a third intermediate pattern which is disposed on the third metal pattern, and a fourth metal pattern which is disposed on the third intermediate pattern and whose grain growth is controlled by the third intermediate pattern.

Each of the wire grid patterns may have a height of 150 to 250 nm.

Each of the metal patterns may have a height of 30 to 70 nm.

Each of the metal patterns may be made of one or more of aluminum (Al), gold (Au), silver (Ag), copper (Cu), chromium (Cr), iron (Fe), nickel (Ni), or a compound thereof.

Each of the intermediate patterns may be an oxide of the metal pattern disposed thereunder.

The wire grid patterns may be spaced apart from one another in a first direction, the intervals having a pitch of 70 to 120 nm in the first direction.

The intermediate patterns, each being an oxide of the metal pattern disposed thereunder, may have a thickness of 0.1 to 5 nm.

Each of the wire grid patterns may include a first film pattern which is disposed on side surfaces the wire grid pattern and a second film pattern which is disposed on a top surface of the wire grid pattern.

Each of the first film pattern and the second film pattern may have a thickness of 3 to 8 nm.

The intermediate patterns may be made of a different metal from the metal patterns.

Each of the metal patterns may be made of one or more of aluminum (Al), gold (Au), silver (Ag), copper (Cu), chromium (Cr), iron (Fe), nickel (Ni), or a compound thereof, and each of the intermediate patterns may be made of one or more of titanium (Ti), cobalt (Co), molybdenum (Mo), niobium (Nb), hafnium (Hf), palladium (Pd), platinum (Pt), rhodium (Rh), tantalum (Ta), or a compound thereof.

Each of the wire grid patterns may include a first film pattern which is disposed on side surfaces of the metal patterns, a second film pattern which is disposed on the top surface of the wire grid pattern, and a third film pattern which is disposed on side surfaces of the intermediate patterns.

Each of the first film pattern, the second film pattern, and the third film pattern may have a thickness of 3 to 8 nm.

The first film pattern and the third film pattern may be disposed alternately on side surfaces of each of the wire grid patterns.

The wire grid polarizer may further include a capping pattern disposed on the fourth metal pattern, the capping pattern being made of a metal different from the fourth metal pattern, or an oxide of the fourth metal pattern.

The capping pattern may have a thickness of 5 to 10 nm.

The wire grid polarizer may further include a buffer pattern between the metal patterns and the substrate.

Embodiments are also directed to a display device including the wire grid polarizer as claimed in claim 1.

Embodiments are also directed to a display device including a protective layer which is disposed on a wire grid polarizer, a gate line which is formed on the protective layer and extends in a first direction, a data line which is insulated from the gate line and extends in a second direction, a thin-film transistor (TFT) which is electrically connected to the gate line and the data line, and a pixel electrode which is electrically connected to the TFT, wherein the wire grid polarizer includes a substrate and a plurality of wire grid patterns on a substrate, the wire grid patterns being arranged on the substrate at regular intervals, each of the wire grid patterns including a plurality of metal patterns in a stack on the substrate with an intermediate pattern interleaved between adjacent metal patterns in the stack.

### BRIEF DESCRIPTION OF THE DRAWINGS

Features will become apparent to those of skill in the art by describing in detail example embodiments with reference to the attached drawings in which:

FIG. 1 illustrates a perspective view of a wire grid polarizer according to an example embodiment;

FIG. 2 illustrates a cross-sectional view of a wire grid pattern according to an example embodiment;

FIGS. 3 through 10 illustrate views illustrating processes of a method of manufacturing a wire grid polarizer according to an example embodiment;

FIG. 11 illustrates a cross-sectional view of a wire grid polarizer according to another example embodiment;

FIGS. 12 and 13 illustrate cross-sectional views of wire grid polarizers according to other example embodiments;

FIGS. 14 through 17 illustrate cross-sectional views of wire grid patterns of wire grid polarizers according to other example embodiments;

FIGS. 18 and 19 illustrate cross-sectional views of wire grid patterns of wire grid polarizers according to other example embodiments;

FIG. 20 illustrates a cross-sectional photograph of a wire grid polarizer according to an example embodiment;

FIG. 21 illustrates a cross-sectional photograph of a wire grid pattern according to an example embodiment;

FIG. 22 illustrates a transmission electron microscopy (TEM) photograph of a metal layer of a wire grid pattern according to an example embodiment;

FIG. 23 illustrates a cross-sectional photograph of a wire grid polarizer according to Comparative Example 1;

FIG. 24 illustrates a TEM photograph of a metal layer of a wire grid pattern according to Comparative Example 1;

FIG. 25 illustrates a perspective view of wire grid patterns according to Comparative Example 1;

FIG. 26 illustrates a perspective view of wire grid patterns according to Comparative Example 2;

FIG. 27 illustrates a graph illustrating extinction ratios of Embodiment and Comparative Examples 1 and 2;

FIG. 28 illustrates a graph illustrating transmittances of Embodiment and Comparative Examples 1 and 2; and

FIG. 29 illustrates a schematic cross-sectional view of a display device including a wire grid polarizer according to another example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art. In the drawing figures, the dimensions of layers and regions may be exaggerated for clarity of illustration. Like reference numerals refer to like elements throughout.

The terminology used herein is for the purpose of describing particular embodiments only and is not intended to be limiting thereof. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to,” or “coupled to” another element or layer, it can be directly on, connected or coupled to the other element or layer or intervening elements or layers may be present. In contrast, when an element is referred to as being “directly on,” “directly connected to,” or “directly coupled to” another element or layer, there are no intervening elements or layers present. As used herein, the term “and/or” includes any and all combinations of one or more of the associated listed items.

It will be understood that, although the terms first, second, etc., may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, these embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

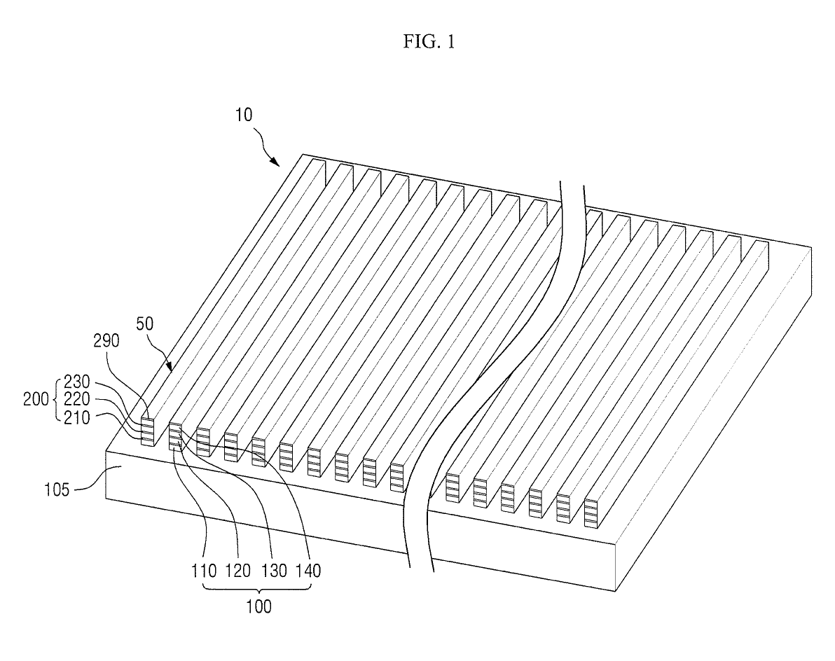

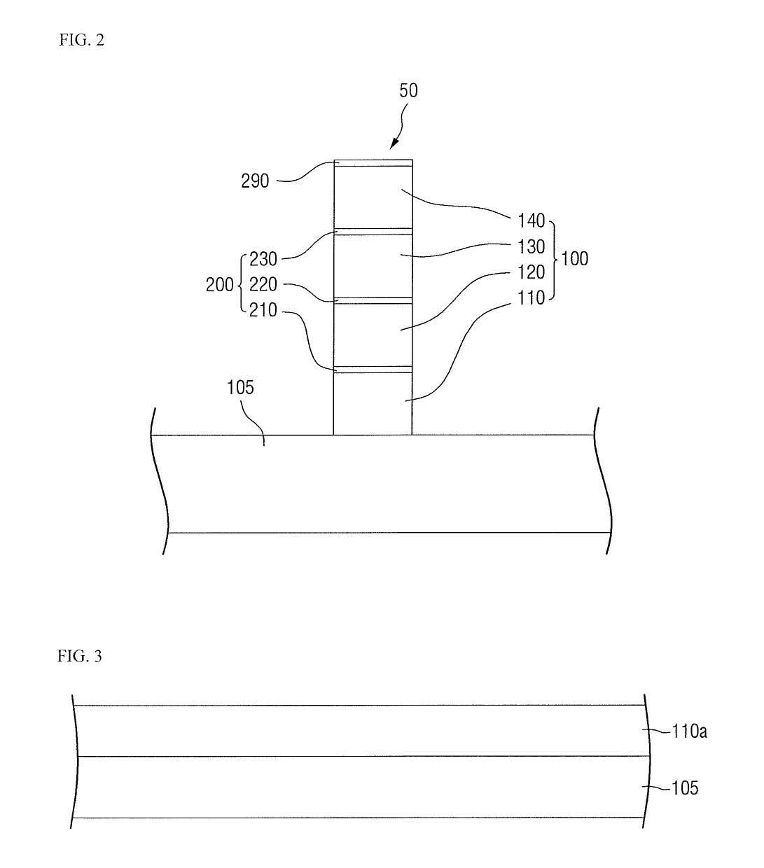

FIG. 1 is a perspective view of a wire grid polarizer 10 according to an example embodiment. FIG. 2 is a cross-sectional view of a wire grid pattern 50 according to an example embodiment.

Referring to FIGS. 1 and 2, the wire grid polarizer 10 includes a plurality of wire grid patterns 50 arranged on a substrate 105 at regular intervals. Here, each of the wire grid patterns 50 includes a plurality of metal patterns 100, which are conductive in a longitudinal direction and which are stacked on the substrate 105, and a plurality of intermediate patterns 200 which are disposed between the metal patterns 100 and control the grain growth of the metal patterns 100 disposed thereon. The metal patterns may include, e.g., first, second, third, and fourth metal patterns 110, 120, 130, and 140, respectively, disposed in a stack.

The substrate 105 may be made of a suitable material that transmits visible light. For example, the substrate 105 may be made of glass, quartz, various polymers such as acrylic, triacetylcellulose (TAC), cyclic olefin copolymer (COC), cyclic olefin polymer (COP), polycarbonate (PC), polyethylene naphthalate (PET), polyimide (PI), polyethylene naphthalate (PEN), polyether sulfone (PES), polyarylate (PAR), etc. The substrate 105 may be made of an optical film material having a certain degree of flexibility.

The wire grid patterns 50 may be arranged on the substrate 105 at regular intervals. To improve the extinction ratio, transmittance, etc. of the wire grid polarizer 10, a ratio of a width and a thickness of each of the wire grid patterns 50, that is, an aspect ratio of each of the wire grid patterns 50, may be 3 or more (thickness/width).

For ease of description, one wire grid pattern 50 will now be described as an example.

In the wire grid pattern 50, a first metal pattern 110 may be disposed on the substrate 105 and may contact the substrate 105. A first intermediate pattern 210 may be disposed on the first metal pattern 110. A second metal pattern 120 may be disposed on the first intermediate pattern 210. The first intermediate pattern 210 may be formed from an intermediate layer that controls the grain growth of metal for the second metal pattern 120 disposed thereon.

In an embodiment, a second intermediate pattern 220 may be disposed on the second metal pattern 120. A third metal pattern 130 may be disposed on the second intermediate pattern 220. The second intermediate pattern 220 may be formed from an intermediate layer that controls the grain growth of metal for the third metal pattern 130 disposed thereon.

A third intermediate pattern 230 may be disposed on the third metal pattern 130. A fourth metal pattern 140 may be disposed on the third intermediate pattern 230. The third intermediate pattern 230 may be formed from an intermediate layer that controls the grain growth of metal for the fourth metal pattern 140 disposed thereon.

In an embodiment, a capping pattern 290 may be disposed on the fourth metal pattern 140.

Each of the first through fourth metal patterns 110 through 140 may have a thickness of 30 to 70 nm. The depositing of each of the first through fourth metal patterns 110 through 140 in the form of layers having a thickness of 70 nm or less may suppress the grain growth of a metal layer that forms each of the first through fourth metal patterns 110 through 140.

When metal for each of the first through fourth metal patterns 110 through 140 is deposited to a thickness of 70 nm or more, grains of each of the first through fourth metal patterns 110 through 140 may be grown in the metal layer. The grown grains may cause surface roughness of the wire grid pattern 50 and cause lateral roughness of the wire grid pattern 50 in a subsequent etching process. This will be described in detail below.

When each of the first through fourth metal patterns 110 through 140 is formed from metal layers deposited to a thickness of less than 30 nm, each metal layer may be deposited repeatedly in order to form the wire grid pattern 50 to a desired height. As the wire grid pattern 50 should be formed to a thickness that satisfies extinction ratio and transmittance conditions, as the number of times the first through fourth metal patterns 110 through 140 are deposited repeatedly to form the wire grid pattern 50 to a predetermined thickness increases, the percentage of process progress may be reduced when using thin metal layers.

In this regard, each of the first through fourth metal patterns 110 through 140 may have a thickness of 30 to 70 nm, for example, 40 to 60 nm.

Metal layers for each of the first through fourth metal patterns 110 through 140 may be deposited to a similar thickness range, or each of the metal layers for the first through fourth metal patterns 110 through 140 may be deposited to a different thickness range according to the size to the grain growth, for example, by changing the deposition atmosphere of each of the metal layers for the first through fourth metal patterns 110 through 140. In the current embodiment, a case where each of the first through fourth metal patterns 110 through 140 have the same thickness is described as an example.

Each of the first through fourth metal patterns 110 through 140 may be made of at least any one of aluminum (Al), gold (Au), silver (Ag), copper (Cu), chromium (Cr), iron (Fe), nickel (Ni), and a compound thereof. Here, all of the first through fourth metal patterns 110 through 140 may be made of the same metal, but the first through fourth metal patterns 110 through 140 may also be made of different metals selected from the above metals.

The first through third intermediate patterns 210 through 230 may be disposed between the first through fourth metal patterns 110 through 140, respectively. In an embodiment, each of the first through third intermediate patterns 210 through 230 may be made of an oxide.

The first through third intermediate patterns 210 through 230 may be formed as oxide films by oxidizing surfaces of the metal layers for the first through third metal patterns 110 through 130 disposed thereunder, respectively. In an embodiment, the first through third intermediate patterns 210 through 230 may also be formed by depositing an oxide on metal layers for at least any one of the first through third metal patterns 110 through 130.

The first through third intermediate patterns 210 through 230 may be disposed on the surfaces of the first through third metal patterns 110 through 130 to provide flat surfaces for each of the second through fourth metal patterns 120 through 140. For example, the first intermediate pattern 210 may be disposed on the first metal pattern 110, and the second metal pattern 120 may be disposed on the first intermediate pattern 210.

The first metal pattern 110 may be formed from a layer that may grow from a seed as it is deposited. Accordingly, roughness of the first metal pattern 110 may be created from the seed. The roughness may worsen as the first metal pattern 110 becomes thicker. However, the first intermediate pattern 210 disposed on the first metal pattern 110 may reduce the roughness.

For example, if metal for the second metal pattern 120 is directly deposited on the metal for the first metal pattern 110 without the first intermediate pattern 210, a convex area formed by the roughness of the metal for the first metal pattern 110 may serve as a seed. Therefore, the metal for the second metal pattern 120 directly deposited on the metal for the first metal pattern 110 having the roughness may have greater surface roughness. For example, the omission of the intermediate layer corresponding to the first intermediate pattern 210 may increase the roughness of the second through fourth metal patterns 120 through 140. According to the current embodiment, the first through third intermediate patterns 210 through 230 may reduce the surface roughness of the wire grid pattern 50 by removing or blocking elements that can serve as seeds of the metal layers of the second through fourth metal patterns 120 through 140.

Each of the first through third intermediate patterns 210 through 230 has a thickness of, for example, 0.1 to 5 nm. The first through third intermediate patterns 210 through 230 may be thinner than the first through fourth metal patterns 110 through 140 and may be disposed on the first through third metal patterns 110 through 130, respectively.

For example, for example, the metal for the first metal pattern 110 may be deposited on the substrate 105 and exposed to air for a predetermined period of time. Then, the material for the intermediate layer forming the first intermediate pattern 210 may be disposed on the exposed surface of the metal for the first metal pattern 110.

Here, when the first metal pattern 110 is made of aluminum (Al), the first intermediate pattern 210 may be an alumina (AlₓO_{y}) layer on the first metal pattern 110. The first intermediate pattern 210 may be an alumina (AlₓO_{y}) layer having a thickness of 0.1 to 5 nm.

The first through fourth metal patterns 110 through 140 may have different refractive indices from those of the first through third intermediate patterns 210 through 230. Thus, the extinction ratio and transmittance of the wire grid polarizer 10 may be reduced. Each of the first through third intermediate patterns 210 through 230 may be grown as a thin film layer.

The capping pattern 290 may be at the top of the wire grid pattern 50. The capping pattern 290 at the top of the wire grid pattern 50 may protect the first through fourth metal patterns 110 through 140 disposed thereunder. In the current embodiment, the capping pattern 290 is disposed at the top of the wire grid pattern 50. In another embodiment, the capping pattern 290 may also be omitted. In the current embodiment, the capping pattern 290 may have a thickness of, for example, 0.1 to 5 nm.

As described above, a plurality of wire grid patterns 50, each including the first through fourth metal patterns 110 through 140 and the first through third intermediate patterns 210 through 230 stacked alternately, may be disposed on the substrate 105. Each of the wire grid patterns 50 disposed on the substrate 105 may have a thickness of, for example, 150 to 250 nm.

The intermediate patterns 200 are stacked alternately between the metal patterns 100 in the wire grid polarizer 10 according to the current embodiment. Thus, the surface roughness of each of the wire grid patterns 50 may be reduced.

The layers forming the intermediate patterns 200 stacked alternately between the metal layers for the metal patterns 100 may control the grain growth of the metal patterns 100. Thus, the lateral roughness of each of the wire grid patterns 50 may be improved, which, in turn, may help increase the extinction ratio and transmittance.

FIGS. 3 through 10 are views illustrating processes of a method of manufacturing a wire grid polarizer according to an example embodiment. Here, the wire grid polarizer will be described with reference to FIGS. 1 and 2.

Referring to FIG. 3, a first metal layer 110a may be deposited on a substrate 105. For example, the substrate 105 may be placed within a chamber, and then the first metal layer 110a may be formed on the substrate 105, e.g., by chemical vapor deposition (CVD) or sputtering. The substrate 105 may be electrically insulating or may have an electrically insulating layer at the surface thereof. A buffer layer, which may be electrically insulating, may be formed on the surface of the substrate 105. The first metal layer 110a may be deposited to a thickness of, for example, 30 to 70 nm.

If the first metal layer 110a is deposited to a thickness of 70 nm or more, grains of the first metal layer 110a may grow. The grown grains may cause surface roughness of wire grid patterns 50 and cause lateral roughness of the wire grid patterns 50 in a subsequent etching process.

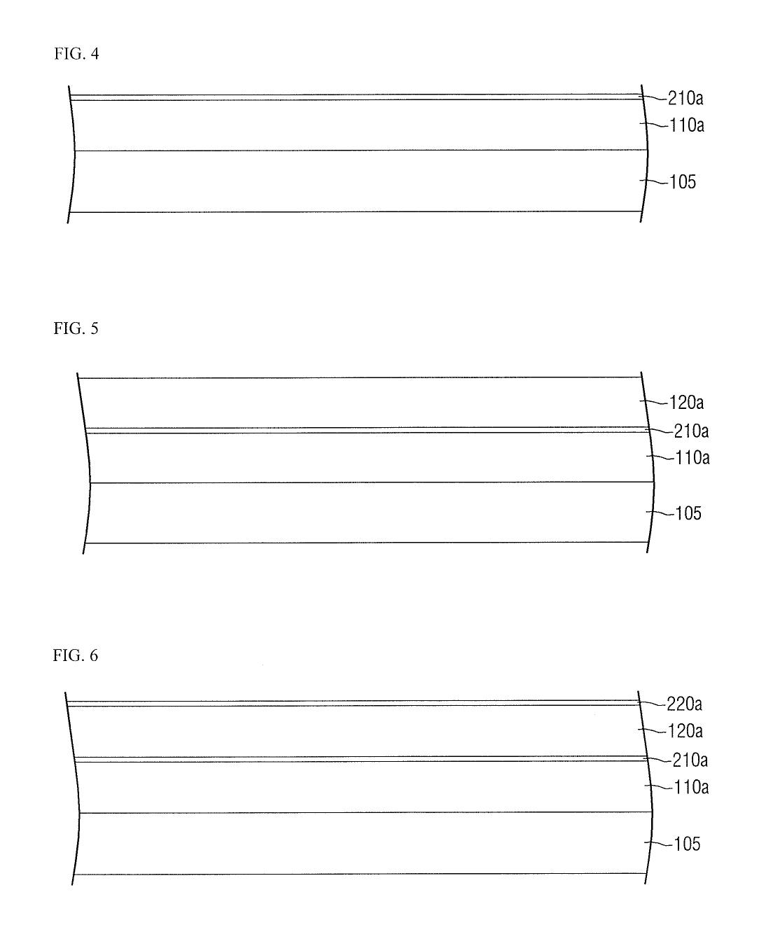

Referring to FIG. 4, after the first metal layer 110a is deposited to a predetermined thickness on the substrate 105, the substrate 105 may be taken out of the chamber to expose the first metal layer 110a to air such that a first intermediate film 210a may be formed as an oxide film on the first metal layer 110a exposed to air. Here, the first intermediate film 210a may be formed as an oxide film to a thickness of 0.1 to 5 nm.

For example, the first metal layer 110a may be formed of aluminum (Al), and the first intermediate film 210a may be formed of alumina (AlₓO_{y}) as an oxide film on the first metal layer 110a. For example, the first intermediate film 210a may be formed as an alumina (AlₓO_{y}) layer to a thickness of 0.1 to 5 nm.

Referring to FIG. 5, the substrate 105 having the first intermediate film 210a may be placed in the chamber again, and then a second metal layer 120a may be formed on the first intermediate layer 210a, e.g., by sputtering.

Referring to FIG. 6, after the second metal layer 120a is deposited to a thickness of 30 to 70 nm, the substrate 105 may be taken out of the chamber again to expose a surface of the second metal layer 120a to air. Then, a second intermediate film 220a may be formed as an oxide film on the second metal layer 120a exposed to air.

In an embodiment, the second metal layer 120a may be the same metal as the first metal layer 110a. In another embodiment, the metal may be different, for example, if the first metal layer 110a is made of aluminum, the second metal layer 120a may be made of molybdenum (Mo). In the current embodiment, a case where the second metal layer 120a is made of the same aluminum metal as the first metal layer 110a is described.

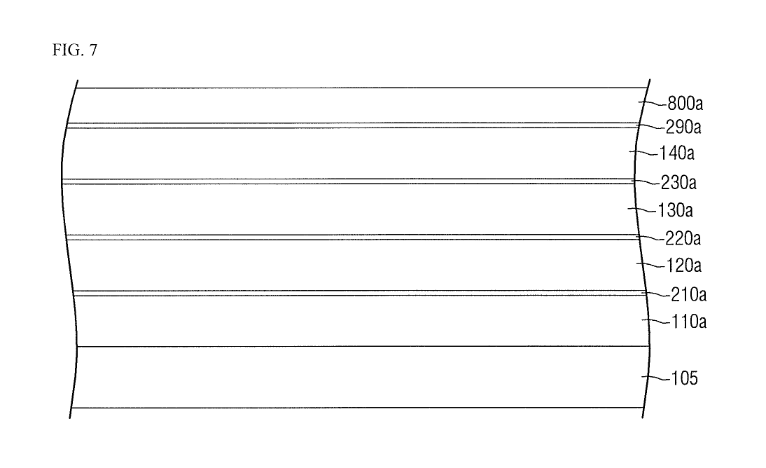

Referring to FIG. 7, the processes of FIGS. 5 and 6 may be continued to form a stack of layers to a predetermined thickness. In an embodiment, the processes of FIGS. 5 and 6 may be repeated to form a wire grid layer to a predetermined thickness.

In an embodiment, a capping layer 290a may be placed on the last formed-metal layer, e.g., on a fourth metal layer 140a. A case where the capping layer 290 is formed as an oxide film like the first through third intermediate films 210a through 230a is described here as an example.

While a case where the first through fourth metal layers 110a through 140a are stacked on the substrate 105 is described here as an example, the first through fourth metal layers 110a through 140a can also be repeatedly deposited two times or more to form the wire grid patterns 50.

When grains of the first through fourth metal layers 110a through 140a are grown to such an extent that makes it difficult to etch the first through fourth metal layers 110a through 140a uniformly, the first through fourth metal layers 110a through 140a can be repeatedly deposited multiple times. For example, the number of times the first through fourth metal layers 110a through 140a are deposited repeatedly may be adjusted according to the grain sizes of the first through fourth metal layers 110a through 140a.

Therefore, the first through fourth metal layers 110a through 140a may be repeatedly deposited two to six times in view of a desired height of each of the wire grid patterns 50. In an embodiment, the first through fourth metal layers 110a through 140a may be repeatedly deposited two to four times.

As described above, the wire grid layer having the first through fourth metal layers 110a through 140a and the first through third intermediate films 210a through 230a stacked alternately may be formed. The above processes may be repeatedly performed to form the wire grid layer to a predetermined height. Here, the wire grid layer may be formed to a height of 150 to 250 nm.

Next, referring to FIG. 7, a photoresist layer 800a is placed on the capping layer 290. The wire grid patterns 50 may be formed by using a photoresist pattern to etch the wire grid layer.

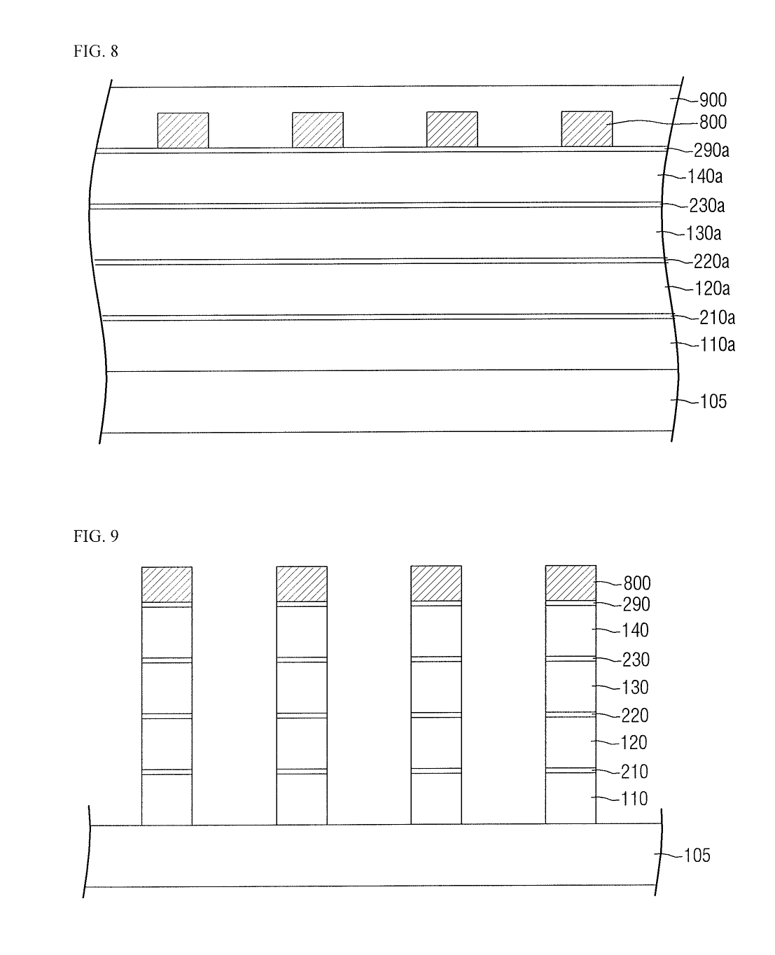

Referring to FIG. 8, a nano-implant mold (hereinafter, referred to as a mold 900) may be placed on the photoresist layer 800a to contact the photoresist layer 800a, thereby forming photoresist patterns 800. Here, a nano-implant method is used as an example of a pattering forming method, but various pattern forming methods such as a photolithography method can be used.

The mold 900 has engraved and embossed patterns, and the material of the photoresist layer 800a is moved by a force generated in the engraved patterns of the mold 900 due to a capillary phenomenon and osmotic pressure. After the movement of the material is completed, the mold 900 is removed from the substrate 105. The removal of the mold 900 may cause the photoresist layer 800a to be formed into the photoresist patterns 800 by the engraved shapes of the mold 900.

Referring to FIG. 9, the wire grid layer may be etched using the photoresist patterns 800 as a mask. Here, the photoresist patterns 800 used as a mask may remain on the wire grid layer.

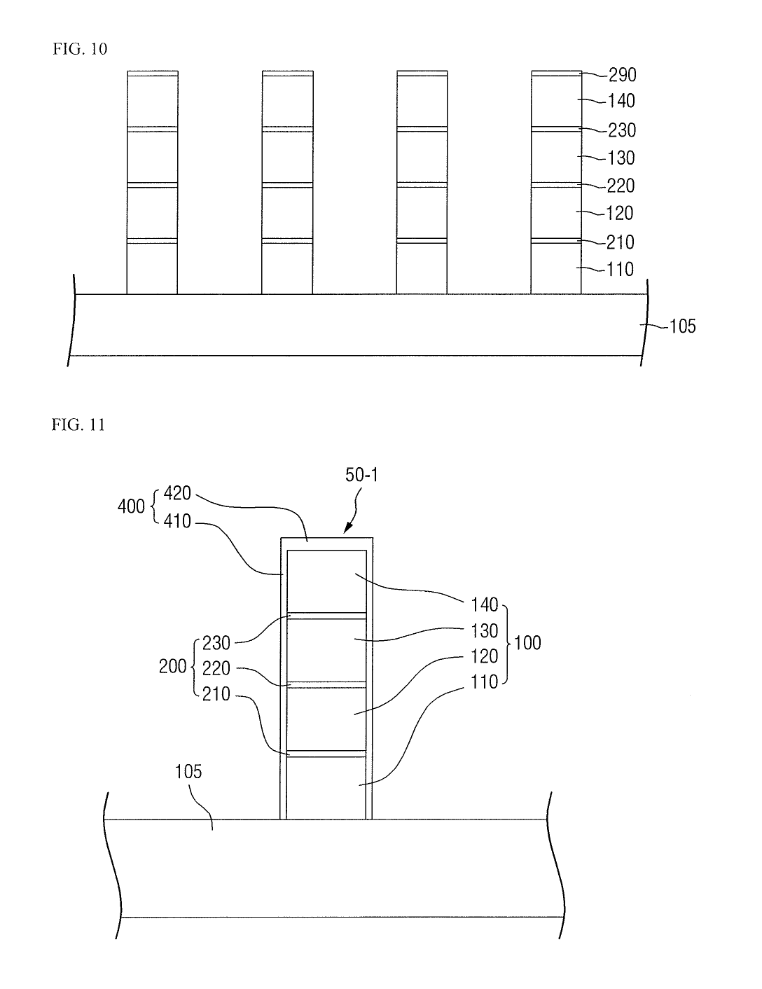

Referring to FIG. 10, after the etching of the wire grid layer is completed, the photoresist patterns 800 may be removed, thereby forming the wire grid patterns 50.

As described above, when the first through third intermediate films 210a through 230a for controlling the grain growth of the second through fourth metal layers 120a through 140a, respectively, are placed between the first through fourth metal layers 110a through 140a, the thickness and edge non-uniformity of each of the wire grid patterns 50 may be improved after the etching. As a result, a wire grid polarizer having improved extinction ratio and transmittance may be provided.

FIG. 11 is a cross-sectional view of a wire grid polarizer 10 according to another example embodiment.

Here, FIGS. 1 and 2 will be cited to avoid any redundant description and for ease of description.

Referring to FIG. 11, the wire grid polarizer 10 may include a plurality of first wire grid patterns 50-1 arranged on a substrate 105. Each of the first wire grid patterns 50-1 may include a plurality of metal patterns 100 which are stacked on the substrate 105 and a plurality of intermediate patterns 200 which are disposed between the metal patterns 100 and formed from layers control the grain growth of metal layers for the metal patterns 100. In addition, a film pattern 400 may be disposed on side and top surfaces of the metal patterns 100 and side and top surfaces of the intermediate patterns 200.

The film pattern 400 may include a first film pattern 410 which is disposed on the side surfaces of the metal patterns 100 and the side surfaces of the intermediate patterns 200, and a second film pattern 420 which is disposed at the top of the metal patterns 100 or the intermediate patterns 200. The film pattern 400 may be formed by oxidizing an exposed surface of each of the wire grid patterns 50 according to the previous embodiment. For example, after etching the metal and intermediate layers to form the wire grid patterns 50, each of the first wire grid patterns 50-1 according to the current embodiment may be formed by forming an oxide on side and top surfaces of each of the wire grid patterns 50.

The first film pattern 410 may be disposed on the side surfaces of each of the first wire grid patterns 50-1 to a thickness of, for example, 5 to 10 nm. The second film pattern 420 may be disposed on the top surface of each of the first wire grid patterns 50-1 to a thickness of, for example, 5 to 10 nm.

When a capping pattern 290 is disposed on each of the first wire grid patterns 50-1, the second film pattern 420 may be disposed on the capping pattern 290 to be thicker than the first film pattern 410. Further, when the capping pattern 290 is formed as an oxide film, the second film pattern 420 may be formed thicker than the first film pattern 410.

As described above, when the intermediate patterns 200 are between the metal patterns 100 and when the film pattern 400 is disposed on the side and top surfaces of the intermediate patterns 200 and the side and top surfaces of the metal patterns 100, the thickness and edge non-uniformity of each of the first wire grid patterns 50-1 may be improved. As a result, a wire grid polarizer 10 having improved extinction ratio and transmittance may be provided.

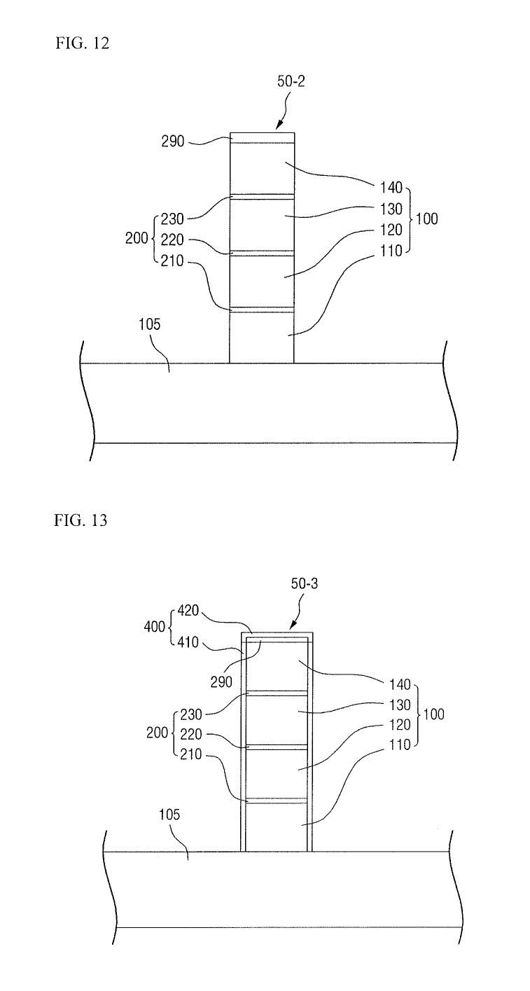

FIGS. 12 and 13 are cross-sectional views of wire grid polarizers 10 according to other example embodiments. Here, FIGS. 1 and 2 will be cited to avoid any redundant description and for ease of description.

First, referring to FIG. 12, the wire grid polarizer 10 includes a plurality of second wire grid patterns 50-2 arranged on a substrate 105 at regular intervals. Here, each of the second wire grid patterns 50-2 may include a plurality of metal patterns 100 which are stacked on the substrate 105 and a plurality of intermediate patterns 200 which are disposed between the metal patterns 100 and formed from layers that control the grain growth of the metal layers for the metal patterns 100 disposed thereon.

A wire grid layer for forming the second wire grid patterns 50-2 may be formed, and layer for the capping pattern 290 may be formed at the top of the wire grid layer to cover the wire grid layer. Here, the capping pattern 290 disposed at the top of each of the second wire grid patterns 50-2 may protect the metal patterns 100 disposed thereunder.

In the current embodiment, the capping pattern 290 may be disposed at the top of each of the second wire grid patterns 50-2. Here, the capping pattern 290 may be made of a different metal from the metal patterns 100. The capping pattern 290 may be made of any one of titanium (Ti), cobalt (Co), molybdenum (Mo), niobium (Nb), hafnium (Hf), palladium (Pd), platinum (Pt), rhodium (Rh), tantalum (Ta), and a compound thereof. In the current embodiment, the capping pattern 290 may have a thickness of, for example, 5 to 10 nm. The capping pattern 290 made of a metal may prevent hillocks of the metal patterns 100 disposed thereunder.

As described above, when the intermediate patterns 200 for controlling the grain growth of the metal patterns 100, respectively, are between the metal patterns 100, the thickness and edge non-uniformity of each of the second wire grid patterns 50-2 may be improved. As a result, a wire grid polarizer 10 having improved extinction ratio and transmittance may be provided.

Referring to FIG. 13, a third wire grid pattern 50-3 may be formed by forming a film pattern 400 formed as an oxide film on an exposed surface of a second wire grid pattern 50-2.

For example, the wire grid polarizer 10 may include a plurality of third wire grid patterns 50-3 arranged on a substrate 105. Each of the third wire grid patterns 50-3 may include a plurality of metal patterns 100 which are stacked on the substrate 105 and a plurality of intermediate patterns 200 which are disposed between the metal patterns 100. The wire grid polarizer 10 may further include the film pattern 400 which is disposed on side and top surfaces of the metal patterns 100 and side and top surfaces of the intermediate patterns 200.

The film pattern 400 may include a first film pattern 410 which is disposed on the side surfaces of the metal patterns 100 and the side surfaces of the intermediate patterns 200 and a second film pattern 420 which is disposed at the top of the metal patterns 100 or the intermediate patterns 200.

The first film pattern 410 may be formed as an oxide film by oxidizing the metal patterns 100. For example, when the metal patterns 100 are made of aluminum (Al), the first film pattern 410 may be made of alumina obtained by oxidizing the aluminum.

In another embodiment, the second film pattern 420 may be made of a different material from the first film pattern 410. For example, when a capping pattern 290 is made of titanium (Ti), the second film pattern 420 formed by oxidizing the capping pattern 290 may be made of titanium oxide (TiOx). Therefore, the second film pattern 420 made of a different material from the first film pattern 410 may be disposed on top and side surfaces of the capping pattern 290.

The first film pattern 410 may be disposed on side surfaces of each of the third wire grid patterns 50-3 to a thickness of 5 to 10 nm. In addition, the second film pattern 420 may be disposed on a top surface of each of the third wire grid patterns 50-3 to a thickness of 5 to 10 nm.

As described above, when the intermediate patterns 200 are between the metal patterns 100 and when the film pattern 400 is disposed on the side and top surfaces of the intermediate patterns 200 and the side and top surfaces of the metal patterns 100, the thickness and edge non-uniformity of each of the third wire grid patterns 50-3 may be improved. As a result, a wire grid polarizer 10 having improved extinction ratio and transmittance may be provided.

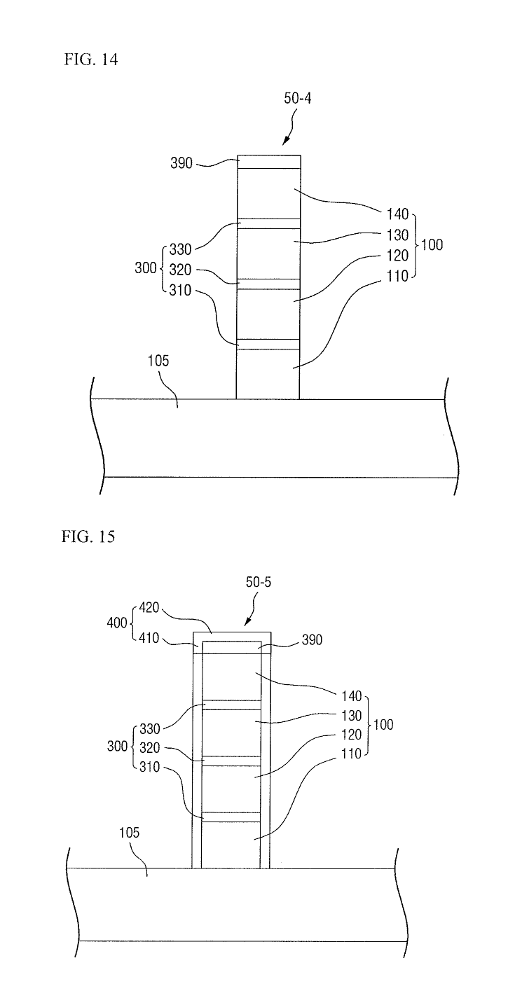

FIGS. 14 through 17 are cross-sectional views of wire grid patterns of wire grid polarizers according to other example embodiments.

FIGS. 14 through 17 will be described with reference to FIGS. 1 through 13 in order to avoid any redundant description and for ease of description.

Referring to FIG. 14, a wire grid polarizer 10 includes a plurality of fourth wire grid patterns 50-4 arranged on a substrate 105 at regular intervals. Here, each of the fourth wire grid patterns 50-4 may include a plurality of metal patterns 100 which are stacked on the substrate 105 and a plurality of intermediate patterns 300 which are disposed between the metal patterns 100.

Each of the intermediate patterns 300 may be made of any one of titanium (Ti), cobalt (Co), molybdenum (Mo), niobium (Nb), hafnium (Hf), palladium (Pd), platinum (Pt), rhodium (Rh), tantalum (Ta), and a compound thereof.

One of the fourth wire grid patterns 50-4 will now be described in greater detail. Of the metal patterns 100, a first metal pattern 110 may be on the substrate 105 and may contact the substrate 105. A (1-1)^{th} intermediate pattern 310 may be disposed on the first metal pattern 110. The (1-1)^{th} intermediate pattern 310 may be formed from a layer that controls the grain growth of a metal layer for the first metal pattern 110 disposed thereunder.

A second metal pattern 120 may be disposed on the (1-1)^{th} intermediate pattern 310. A (2-1)^{th} intermediate pattern 320 may be disposed on the second metal pattern 120. The (2-1)^{th} intermediate pattern 320 may be formed from a layer that controls the grain growth of a metal layer for the second metal pattern 120 disposed thereunder.

A third metal pattern 130 may be disposed on the (2-1)^{th} intermediate pattern 320. A (3-1)^{th} intermediate pattern 330 may be disposed on the third metal pattern 130. The (3-1)^{th} intermediate pattern 330 may be formed from a layer that controls the grain growth of a metal layer for the third metal pattern 130 disposed thereunder.

A fourth metal pattern 140 may be disposed on the (3-1)^{th} intermediate pattern 330, and a capping pattern 390 may be disposed on the fourth metal pattern 140.

Each of the first through fourth metal patterns 110 through 140 may be made of at least any one of aluminum (Al), gold (Au), silver (Ag), copper (Cu), chromium (Cr), iron (Fe), nickel (Ni), and a compound thereof. Here, all of the first through fourth metal patterns 110 through 140 may be made of the same metal, but the first through fourth metal patterns 110 through 140 may also be made of different metals selected from the above metals.

The first metal pattern 110 may have a height of 30 to 70 nm. Each of the first through fourth metal patterns 110 through 140 have a similar thickness range, or each of the first through fourth metal patterns 110 through 140 may have a different thickness according to the size to the grain growth by changing the deposition atmosphere of each of the metal layers for the first through fourth metal patterns 110 through 140. In the current embodiment, a case where each of the first through fourth metal patterns 110 through 140 has the same thickness is described as an example.

Each of the (1-1)^{th} through (3-1)^{th} intermediate patterns 310 through 330 disposed on the first metal pattern 110 may be made of any one of titanium (Ti), cobalt (Co), molybdenum (Mo), niobium (Nb), hafnium (Hf), palladium (Pd), platinum (Pt), rhodium (Rh), tantalum (Ta), and a compound thereof.

The (1-1)^{th} through (3-1)^{th} intermediate patterns 310 through 330 may be disposed on the first through third metal patterns 110 through 130, respectively. The (1-1)^{th} through (3-1)^{th} intermediate patterns 310 through 330 may be made of the same metal. In another embodiment, when the (1-1)^{th} intermediate pattern 310 is made of titanium (Ti), the (2-1)^{th} intermediate pattern 320 and the (3-1)^{th} intermediate pattern 330 may be made of molybdenum (Mo). Each of the (1-1)^{th} through (3-1)^{th} intermediate patterns 310 through 330 may have a thickness of 0.1 to 5 nm.

For example, the metal for the first metal pattern 110 may be deposited to a thickness of 30 to 70 nm on the substrate 105, and layer for the (1-1)^{th} intermediate pattern 310 may be formed on the first metal pattern 110. Here, layers for the first metal pattern 110 and the (1-1)^{th} intermediate pattern 310 may be formed within the same chamber by changing a gas atmosphere. The layers for first metal pattern 110 and/or the (1-1)^{th} intermediate pattern 310 may be formed by CVD or sputtering.

Here, the layer for the (1-1)^{th} intermediate pattern 310 may be deposited to a thickness of, for example, 0.1 to 5 nm. The layer for the (1-1)^{th} intermediate pattern 310 may be grown to a minimum thickness because different refractive indices of the first through fourth metal patterns 110 through 140 and the (1-1)^{th} through (3-1)^{th} intermediate patterns 310 through 330 may reduce the extinction ratio and transmittance of the wire grid polarizer 10.

Next, the metal for the second metal pattern 120 may be formed on the layer for the (1-1)^{th} intermediate pattern 310. The second metal pattern 120 may be the same metal pattern as the first metal pattern 110. Next, the layer for the (2-1)^{th} intermediate pattern 320 may be formed on the layer for the second metal pattern 120. The above process may be repeatedly performed on the layer for the (2-1)^{th} intermediate pattern 320 to form a wire grid layer having a predetermined height.

Each of the fourth wire grid patterns 50-4 may be formed by etching the wire grid layer having the first through fourth metal patterns 110 through 140 and the (1-1)^{th} through (3-1)^{th} intermediate patterns 310 through 330 stacked alternately. For example, the wire grid layer may be stacked to a thickness of 150 to 250 nm, and the fourth wire grid patterns 50-4 may be formed to a height of 150 to 250 nm on the substrate 105 by etching the wire grid layer.

The wire grid layer for forming the fourth wire grid patterns 50-4 may be formed, and the capping pattern 390 may be formed at the top of the wire grid layer to cover the wire grid layer. The capping pattern 390 formed at the top of each of the fourth wire grid patterns 50-4 may protect the first through fourth metal patterns 110 through 140 disposed thereunder. In the current embodiment, the capping pattern 390 may be formed to a thickness of 0.1 to 5 nm; the capping pattern 390 may also be formed thicker than the (1-1)^{th} through (3-1)^{th} intermediate patterns 310 through 330 in order to protect the first through fourth metal patterns 110 through 140 disposed thereunder.

As described above, when the layers forming the intermediate patterns 300 for controlling the grain growth of the metal patterns 100, respectively, are formed between the layers for the metal patterns 100, the thickness and edge non-uniformity of each of the fourth wire grid patterns 50-4 may be improved. As a result, a wire grid polarizer 10 having improved extinction ratio and transmittance may be provided.

Referring to FIG. 15, a fifth wire grid pattern 50-5 may be formed by forming an oxide film on the fourth wire grid pattern 50-4 of FIG. 14. The fifth wire grid pattern 50-5 may include a first film pattern 410 which is formed on side surfaces of metal patterns 100 and side surfaces of (1-1)^{th} through (3-1)^{th} intermediate patterns 310 through 330. Here, since the (1-1)^{th} through (3-1)^{th} intermediate patterns 310 through 330 are formed as thin films, the oxide film disposed on the side surfaces of the metal patterns 100 may diffuse to the side surfaces of the (1-1)^{th} through (3-1)^{th} intermediate patterns 310 through 330, thereby forming the first film pattern 410.

In addition, a second film pattern 420 may be formed as an oxide film on a capping pattern 390. Here, the second film pattern 420 disposed on the capping pattern 390 may be made of a different oxide from the first film pattern 410.

As described above, when intermediate patterns 300 are between the metal patterns 100 and when a film pattern 400 is placed on the side and top surfaces of the intermediate patterns 300 and the metal patterns 100, the thickness and edge non-uniformity of the fifth wire grid pattern 50-5 may be improved. As a result, a wire grid polarizer 10 having improved extinction ratio and transmittance may be provided.

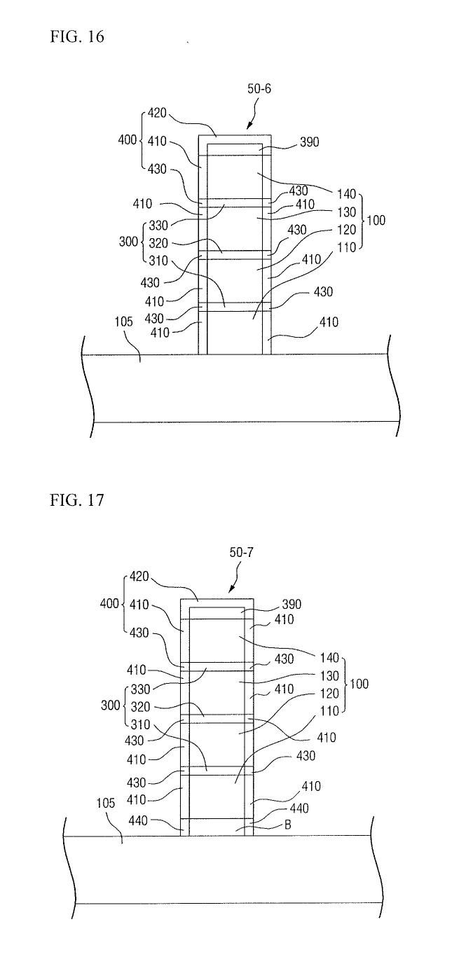

Referring to FIG. 16, unlike the fifth wire grid pattern 50-5, a sixth wire grid pattern 50-6 may include a third film pattern 430 disposed on side surfaces of (1-1)^{th} through (3-1)^{th} intermediate patterns 310 through 330. Here, a first film pattern 410 and the third film pattern 430 may be alternately disposed on side surfaces of the sixth wire grid pattern 50-6.

The third film pattern 430 may be made of a different oxide from the first film pattern 410. For example, since the (1-1)^{th} through (3-1)^{th} intermediate patterns 310 through 330 are made of a different metal from first through fourth metal patterns 110 through 140, the third film pattern 430 disposed on the side surfaces of the (1-1)^{th} through (3-1)^{th} intermediate patterns 310 through 330 may have different components from the first film pattern 410 disposed on side surfaces of the first through fourth metal patterns 110 through 140.

As described above, when intermediate patterns 300 are between the metal patterns 100 and when a film pattern 400 is placed on side and top surfaces of the intermediate patterns 300 and the metal patterns 100, the thickness and edge non-uniformity of the sixth wire grid pattern 50-6 may be improved. As a result, a wire grid polarizer 10 having improved extinction ratio and transmittance may be provided.

Referring to FIG. 17, unlike the sixth wire grid pattern 50-6 of FIG. 16, a seventh wire grid pattern 50-7 may include a buffer pattern B disposed under the sixth wire grid pattern 50-6, for example, between the sixth wire grid pattern 50-6 and a substrate 105.

Here, a fourth film pattern 440 may further be disposed on side surfaces of the buffer pattern B. The buffer pattern B may improve adhesion between the substrate 105 and a first metal pattern 110. In addition, the buffer pattern B may prevent the diffusion of an alkali component of the substrate 105, such as a glass substrate, into the first metal pattern 110.

A material used for the buffer pattern B may have a similar reflectivity and refractive index to those of the first metal pattern 110. The material of the buffer pattern B may be selected to improve the adhesion between the substrate 105 and the first metal pattern 110.

As described above, when intermediate patterns 300 are between the metal patterns 100, when a film pattern 400 is placed on side and top surfaces of the intermediate patterns 300 and the metal patterns 100, and when the buffer pattern B is disposed between the substrate 105 and the first metal pattern 110, the thickness and edge non-uniformity of the seventh wire grid pattern 50-7 may be improved. As a result, a wire grid polarizer 10 having improved extinction ratio and transmittance may be provided.

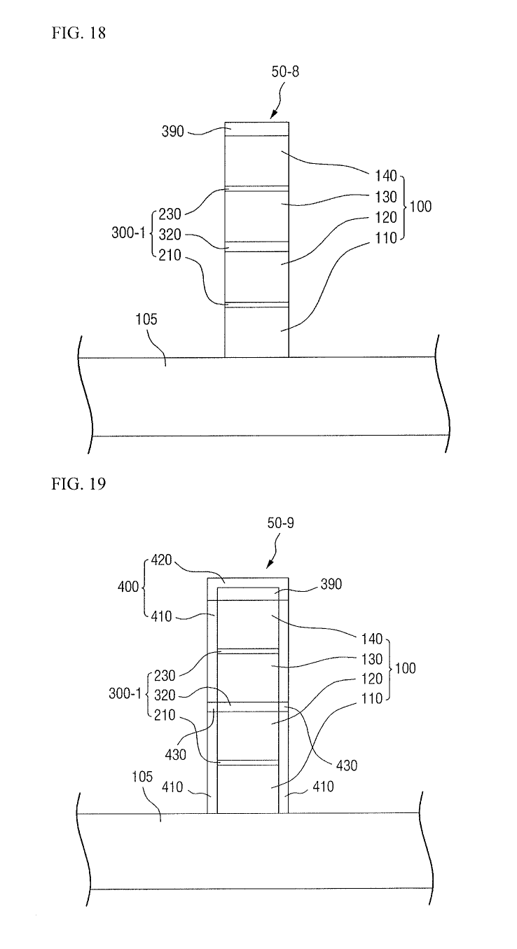

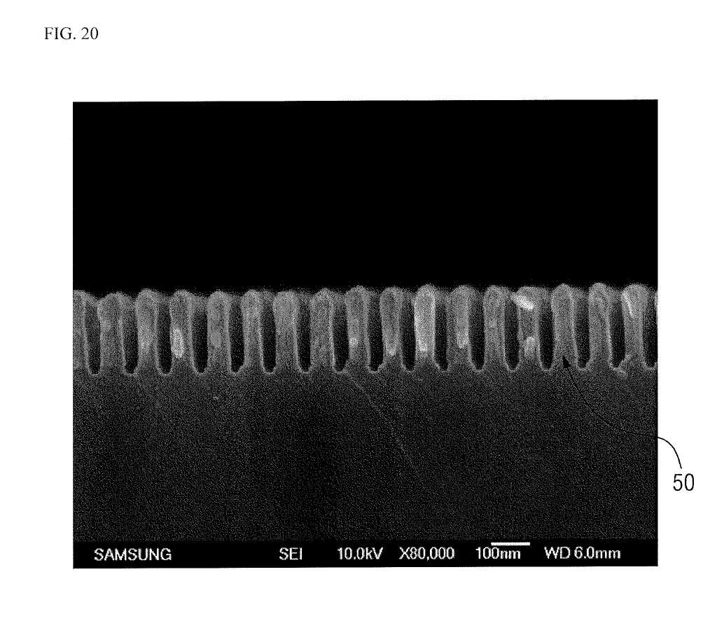

FIGS. 18 and 19 are cross-sectional views of wire grid patterns of wire grid polarizers according to other example embodiments.

Hereinafter, FIGS. 18 and 19 will be described with reference to FIGS. 1 through 17 in order to avoid any redundant description and for ease of description.

Referring to FIG. 18, unlike the seventh wire grid pattern 50-7, an eighth wire grid pattern 50-8 may include a first intermediate pattern 210 disposed on a first metal pattern 110, a second metal pattern 120 disposed on the first intermediate pattern 210, and a (2-1)^{th} intermediate pattern 320 disposed on the second metal pattern 120. In addition, a third metal pattern 130 may be disposed on the (2-1)^{th} intermediate pattern 320, and a third intermediate pattern 230 may be disposed on the third metal pattern 130.

A fourth metal pattern 140 may be disposed on the third intermediate pattern 230, and a capping pattern 390 may be disposed on the fourth metal pattern 140. Here, the capping pattern 390 or the (2-1)^{th} intermediate pattern may be made of any one of titanium (Ti), cobalt (Co), molybdenum (Mo), niobium (Nb), hafnium (Hf), palladium (Pd), platinum (Pt), rhodium (Rh), tantalum (Ta), and a compound thereof. The capping pattern 390 and the (2-1)^{th} intermediate pattern 320 may be made of the same material or different materials.

As described above, when intermediate patterns 300-1 are between the metal patterns 100, the thickness and edge non-uniformity of the eighth wire grid pattern 50-8 may be improved. As a result, a wire grid polarizer 10 having improved extinction ratio and transmittance may be provided.

Referring to FIG. 19, a ninth wire grid pattern 50-9 may be formed by forming an oxide film on a surface of the eighth wire grid pattern 50-8 of FIG. 18.

The ninth wire grid pattern 50-9 may include a first film pattern 410 disposed on side surfaces of a first metal pattern 110. Here, the first film pattern 410 may be made of the same material as a first intermediate pattern 210.

A third film pattern 430 may be disposed on the first film pattern 410. The third film pattern 430 may be formed by forming an oxide film on a (2-1)^{th} intermediate pattern 320. The first film pattern 410 and the third film pattern 430 may be made of different materials.

The first film pattern 410 may be disposed on the third film pattern 430. The first film pattern 410 disposed on the third film pattern 430 may be made of the same material as a third intermediate pattern 230.

A second film pattern 420 may be disposed on the first film pattern 410 disposed on side surfaces of the third intermediate pattern 230. The second film pattern 420 may be formed by forming an oxide film on a capping pattern 390. Here, when the capping pattern 390 and the (2-1)^{th} intermediate pattern 320 are made of the same material, the third film pattern 430 and the second film pattern 420 may be made of the same material.

Therefore, the first film pattern 410 may alternate with the third film pattern 430 or the second film pattern 420.

As described above, when intermediate patterns 300-1 are between the metal patterns 100 by alternately forming oxides and metals, and when a film pattern 400 is formed on side and top surfaces of the intermediate patterns 300-1 and the metal patterns 100, the thickness and edge non-uniformity of the ninth wire grid pattern 50-9 may be improved. As a result, a wire grid polarizer 10 having improved extinction ratio and transmittance may be provided.

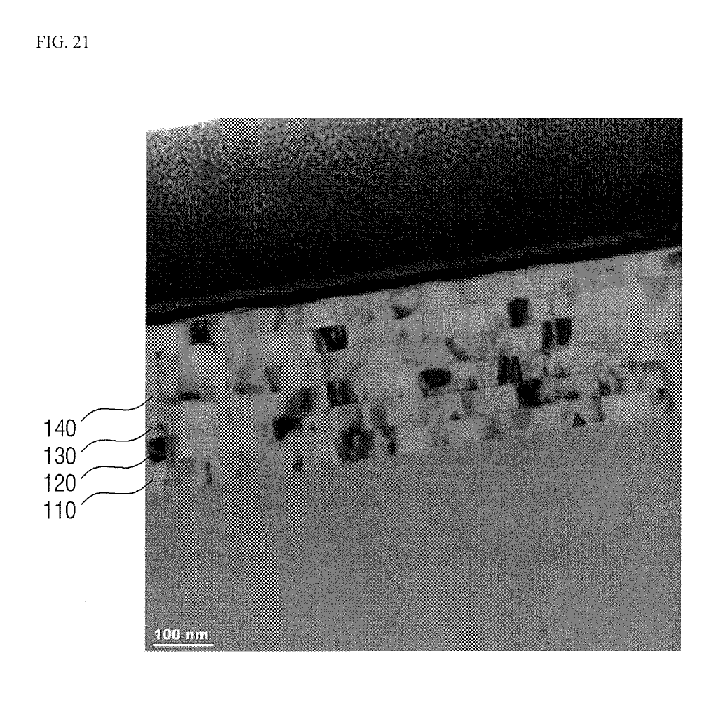

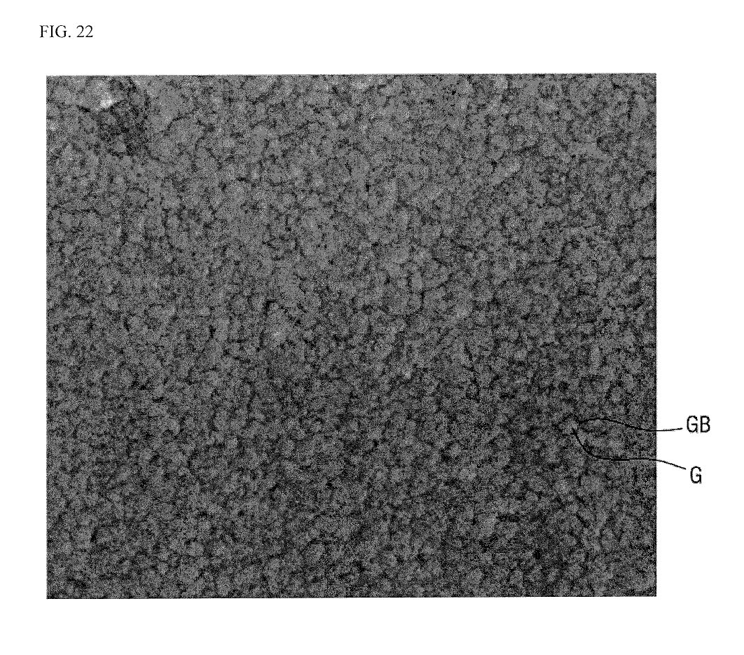

FIG. 20 is a cross-sectional photograph of a wire grid polarizer according to an example embodiment. FIG. 21 is a cross-sectional photograph of a wire grid pattern according to an example embodiment. FIG. 22 is a transmission electron microscopy (TEM) photograph of a metal layer of a wire grid pattern according to an example embodiment.

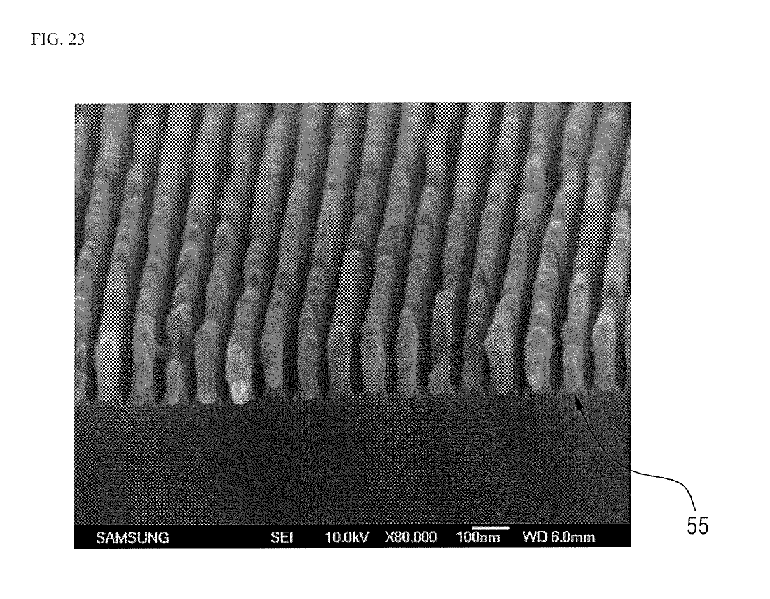

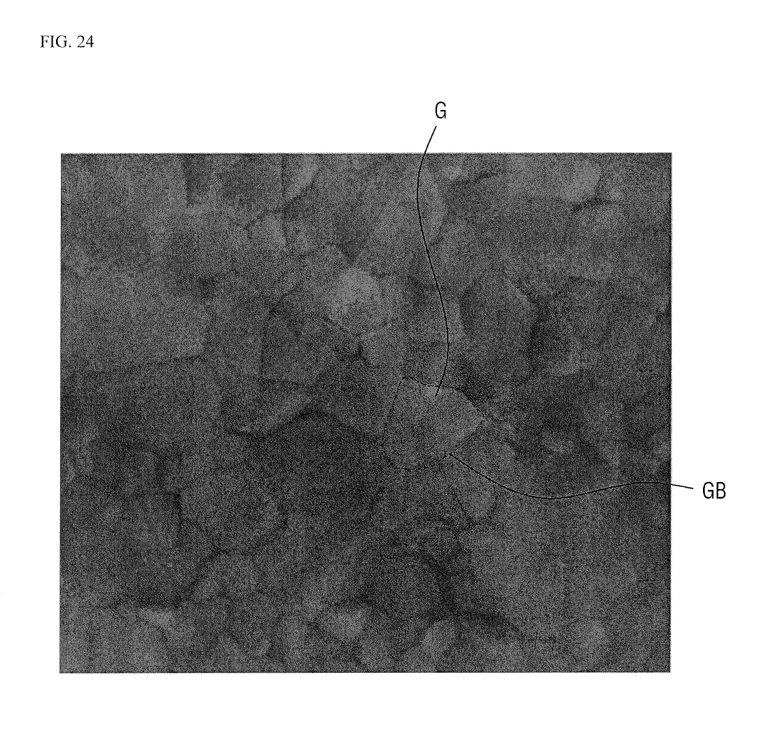

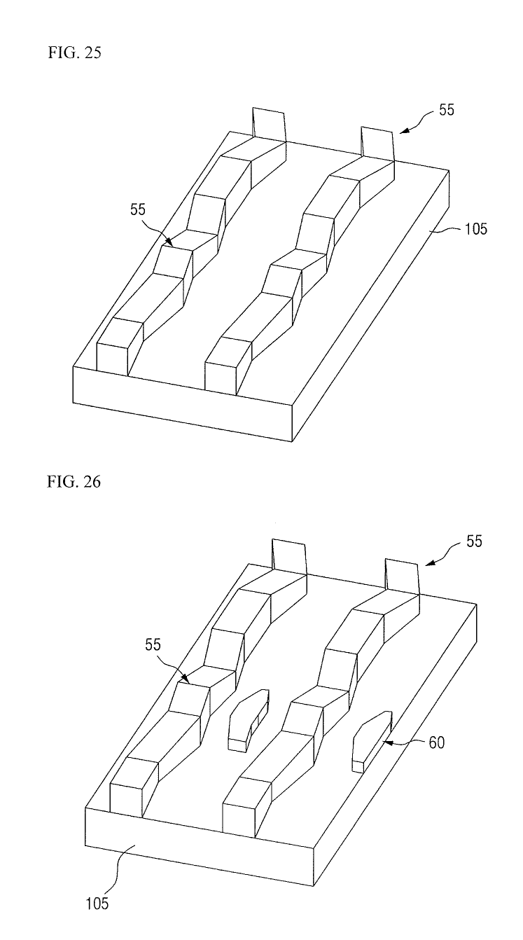

FIG. 23 is a cross-sectional photograph of a wire grid polarizer according to Comparative Example 1. FIG. 24 is a TEM photograph of a metal layer of a wire grid pattern according to Comparative Example 1. FIG. 25 is a perspective view of wire grid patterns according to Comparative Example 1. FIG. 26 is a perspective view of wire grid patterns according to Comparative Example 2.

Hereinafter, FIGS. 20 through 26 will be described with reference to FIGS. 1 through 19 in order to avoid any redundant description and for ease of description. In particular, FIGS. 1 and 2 will be cited as representative drawings.

Referring to FIGS. 20, 21 and 23, a wire grid polarizer 10 having a plurality of wire grid patterns 50 on a substrate 105 is shown.

Referring to FIG. 20, the wire grid patterns 50 are arranged at equal pitches. In addition, the wire grid patterns 50 have equal heights. On the other hand, referring to FIG. 23, wire grid patterns 55 are arranged at unequal pitches and have unequal heights.

Referring to FIGS. 22 and 24, in a cross-sectional photograph of a metal layer which forms a wire grid pattern, grains grown in the metal layer is shown.

Referring to FIG. 22, in a wire grid pattern according to an embodiment, a metal pattern is deposited to a thickness of 30 to 70 nm and grain growth in the metal for the metal pattern may be suppressed. Accordingly, the grain size of the grains G in the metal pattern is small, and a grain boundary GB surrounding each grain G is fine.

On the other hand, referring to FIG. 24, grains G of a metal layer of Comparative Example 1 have grown significantly to large sizes. Therefore, grain boundaries GB of the grains G are clearly visible. In addition, since the grains G have grown to large sizes, there is a large difference in size between the grain boundaries GB.

When the metal layer having the grains G grown to different sizes as described above is etched, grain boundary areas having defects may be etched first.

For example, when grains and grain boundaries have grown significantly as in Comparative Example 1, etching may occur from grain boundary areas first. Here, since the grain boundaries are formed irregularly, it is difficult to maintain pattern straightness and roughness through the etching.

Referring to the cross-section of a wire grid pattern in the embodiment of FIG. 13, the growth of grains and grain boundaries may be controlled by depositing a metal layer to be separated from another metal layer. Here, a layer for an intermediate pattern 200 may be placed between layers for metal patterns 100 to control the growth of the grains and grain boundaries of the metal layer.

If the growth of grains and grain boundaries is controlled as described above, fine grains and fine grain boundaries may be formed. Therefore, pattern straightness and roughness may be easily maintained during etching.

Accordingly, referring to FIG. 20, since the growth of grains and grain boundaries is controlled in the process of forming the wire grid patterns, the straightness and roughness of the wire grid patterns may be improved.

As described above, when the intermediate patterns are between the metal patterns, the thickness and edge non-uniformity of the wire grid patterns may be improved. As a result, a wire grid polarizer having improved extinction ratio and transmittance may be provided. On the other hand, if the growth of grains and grain boundaries is not controlled in the process of forming the wire grid patterns, the grains and the grain boundaries may grow to deteriorate the straightness and roughness of the wire grid patterns.

FIGS. 25 and 26 are schematic perspective views of wire grid patterns formed by etching a metal layer after the growth of grains and grain boundaries.

In Comparative Example 1 of FIG. 25, wire grid patterns 55 disposed on a substrate have severe roughness due to their unequal heights. In addition, the straightness of the wire grid patterns 55 has been reduced to such an extent that the wire grid patterns 55 cannot be perceived as being arranged at regular pitches.

This is because the growth of grains and grain boundaries caused etching to be performed from the irregular grain boundaries, thus deteriorating the straightness and roughness of the wire grid patterns 55.

In Comparative Example 2 of FIG. 26, wire grid patterns 55 disposed on a substrate have severe roughness due to their unequal heights. In addition, the straightness of the wire grid patterns 55 has been reduced to such an extent that the wire grid patterns 55 cannot be perceived as being arranged at regular pitches. Further, a residual pattern 60 has been formed between the wire grid patterns 55.

This is also because grains and grain boundaries caused etching to be performed on some areas first and on some other areas later, resulting in the formation of the residual pattern 60 between the wire grid patterns 55.

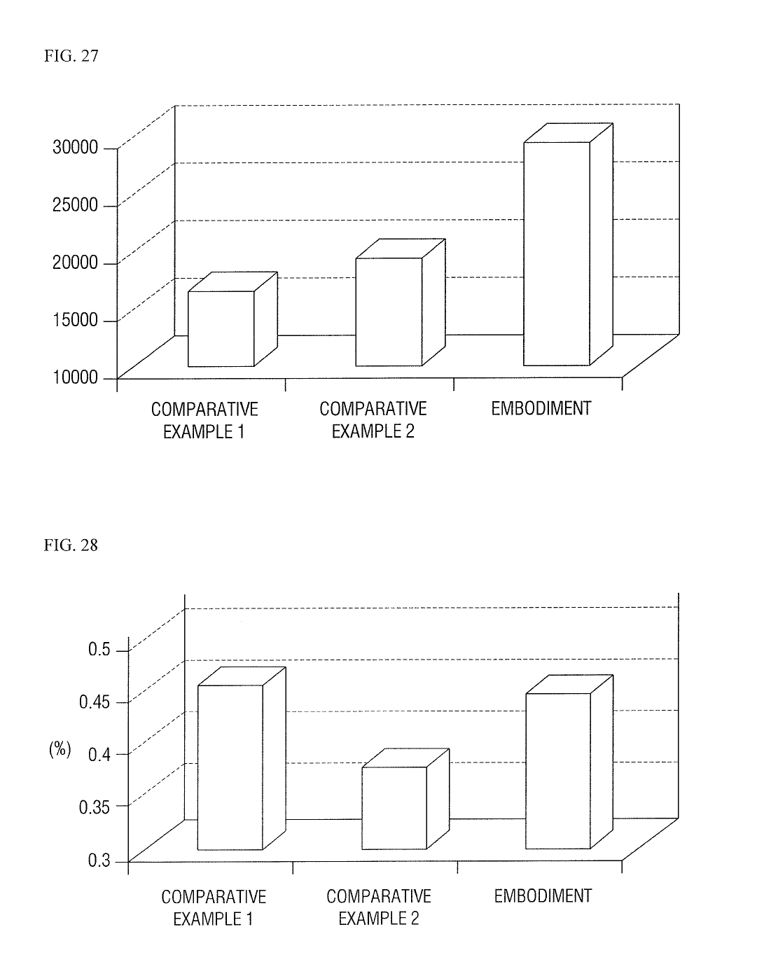

FIG. 27 is a graph illustrating extinction ratios of an example according to an Embodiment relative to Comparative Examples 1 and 2. FIG. 28 is a graph illustrating transmittances of Embodiment relative to Comparative Examples 1 and 2.

Referring to FIG. 27, the extinction ratio of Comparative Example 1 was measured to be 15500 to 16500, and the extinction ratio of Comparative Example 2 was measured to be 17000 to 18000.

On the other hand, the extinction ratio of Embodiment was measured to be 27000 to 28000. Therefore, it can be understood that the extinction ratio has improved significantly.

Referring to FIG. 28, the transmittance of Comparative Example 1 was measured to be 43 to 44%, and the transmittance of Comparative Example 2 was measured to be 36 to 37%.

The transmittance of Comparative Example 2 decreased significantly due to the residual pattern 60. On the other hand, the transmittance of Embodiment was measured to be 43 to 44%.

As apparent from the above description, extinction ratio and transmittance have a trade-off relationship and can be adjusted through the above embodiments.

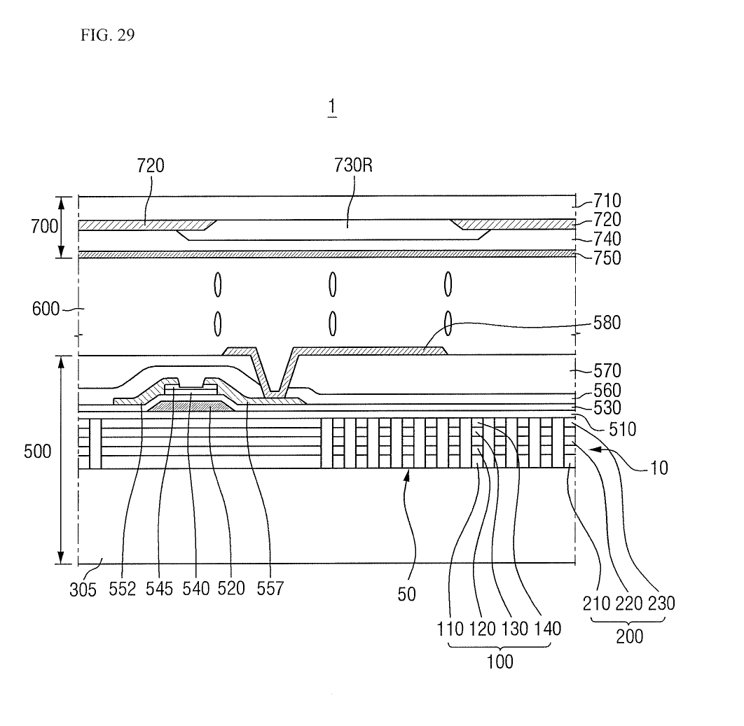

FIG. 29 is a schematic cross-sectional view of a display device 1 including a wire grid polarizer 10 according to another example embodiment. Hereinafter, the wire grid polarizer will be described with reference to FIGS. 1 through 28. In particular, FIGS. 1 and 2 will be cited as representative drawings.

Referring to FIG. 29, the display device 1 may include a first display substrate 500, a second display substrate 700 which is separated from the first display substrate 500 to face the first display substrate 500, and a liquid crystal layer 600 which is interposed between the first display substrate 500 and the second display substrate 700. The display substrates 500 and 700 may include a plurality of pixels arranged in a matrix pattern.

The first display substrate 500 may include a plurality of gate lines extending in a first direction and a plurality of data lines extending in a second direction perpendicular to the first direction. A pixel electrode 580 may be disposed in each pixel defined by a gate line and a data line.

The pixel electrode 580 may receive a data voltage through a thin-film transistor (TFT) which is a switching device. A gate electrode 520 which is a control terminal of the TFT may be connected to a gate line, a source electrode 552 which is an input terminal may be connected to a data line, and a drain electrode 557 which is an output terminal may be connected to the pixel electrode 580 by a contact hole. A channel of the TFT may be formed as a semiconductor layer 540. An ohmic contact layer 545 having a high work function may further be disposed between the semiconductor layer 540 and each of the source and drain electrodes 552 and 557. The ohmic contact layer 545 may be made to have a high work function by doping the semiconductor layer 540 with a dopant.

The semiconductor layer 540 may overlap the gate electrode 520. The source electrode 552 and the drain electrode 557 may be separated from each other with respect to the semiconductor layer 540. The pixel electrode 580 may form an electric field together with a common electrode 570, thereby controlling the alignment direction of liquid crystal molecules of the liquid crystal layer 600 interposed therebetween. The liquid crystal layer 600 may be, but is not limited to, of a twisted nematic (TN), vertical alignment (VA), or horizontal alignment (IPS, FFS) mode having positive dielectric anisotropy.

A color filter 730 may be formed in each pixel of the second display substrate 700. The color filters 730 may include red, green, and blue color filters. The red, green, and blue color filters 730 may be arranged alternately. A light-blocking pattern 720 may be disposed at a boundary between every two color filters 730. In addition, the light-blocking pattern 720 may be disposed up to a non-display area of the second display substrate 700. The common electrode 750 formed as a single piece regardless of the pixels may be disposed in the second display substrate 700.

The display device 1 will now be described in greater detail.

The first display substrate 500 may use the wire grid polarizer 10 having wire grid patterns 50 as a base substrate. Here, the wire grid polarizer 10 having the wire grid patterns 50 of FIG. 1 is described as a representative example. However, a wire grid polarizer 10 including any of the wire grid patterns 50-1 through 50-9 according to other example embodiments can also be used.

A substrate 105 may be a transparent insulating substrate made of glass or transparent plastic.

The wire grid polarizer 10 may include a protective layer 510 formed on the wire grid patterns 50. The protective layer 510 may protect and insulate the wire grid patterns 50.

The wire grid patterns 50 may protrude upward from the substrate 105.

Each of the wire grid patterns 50 include a plurality of metal patterns 100 which are stacked on the substrate 105 and a plurality of intermediate patterns 200 which are disposed between the metal patterns 100 and formed from layers that control the grain growth of the layers for the metal patterns 100 disposed thereunder.

With the intermediate patterns 200 are between the metal patterns 100, the thickness and edge non-uniformity of the wire grid patterns 50 may be improved. As a result, a wire grid polarizer 10 having improved extinction ratio and transmittance may be provided.

A gate line made of a conductive material and the gate electrode 520 protruding from the gate line may be formed on the protective layer 530 of the wire grid polarizer 10. The gate line may extend up to the non-display area and form a gate pad in the non-display area.

The gate line and the gate electrode 520 are covered by a gate insulating layer 530.

The semiconductor layer 540 and the ohmic contact layer 545 may be formed on the gate insulating layer 530. The source electrode 552 branching from a data line and a drain electrode 557 separated from the source electrode 552 may be formed on the semiconductor layer 540 and the ohmic contact layer 545. Although not illustrated in the drawing, the data line may extend up to the non-display area and form a data pad in the non-display area.

A passivation layer 560 may be formed on the source electrode 552 and the drain electrode 557. The passivation layer 560 is a kind of an insulating layer made of an insulating material, such as a silicon nitride layer, a silicon oxide layer, or a silicon oxynitride layer. An organic layer 570 made of an organic material may be disposed on the passivation layer 560. The passivation layer 560 and the organic layer 570 may be formed up to the non-display area. The passivation layer 560 can be omitted.

The pixel electrode 580 made of a conductive material may be formed on the organic layer 570 in each pixel. The pixel electrode 580 may be electrically connected to the drain electrode 557 by the contact hole which penetrates through the organic layer 570 and the passivation layer 560 to expose the drain electrode 557. The pixel electrode 580 may be made of indium tin oxide, indium zinc oxide, indium oxide, zinc oxide, tin oxide, gallium oxide, titanium oxide, aluminum, silver, platinum, chrome, molybdenum, tantalum, niobium, zinc, magnesium, an alloy thereof, or a stacked layer thereof.

The second display substrate 700 will now be described. The second display substrate 700 uses a second substrate 710 as a base substrate. The second substrate 710 may be a transparent insulating substrate made of glass or transparent plastic.

The light-blocking pattern 720 is formed on the second substrate 710. The light-blocking pattern 720 may be formed up to the non-display area.

The color filters 730 may be formed on the light-blocking pattern 720 in a display area.

An overcoating layer 740 may be formed on the color filters 730 and the light-blocking pattern 720. The overcoating layer 740 may be formed up to the non-display area.

The common electrode 750 may be disposed on the overcoating layer 740. The common electrode 750 may be made of indium tin oxide, indium zinc oxide, indium oxide, zinc oxide, tin oxide, gallium oxide, titanium oxide, aluminum, silver, platinum, chrome, molybdenum, tantalum, niobium, zinc, magnesium, an alloy thereof, or a stacked layer thereof.

The common electrode 750 may cover the entire display area. However, the common electrode 750 may include slits or openings in the display area.

The common electrode 750 can be formed up to part of the non-display area. However, the common electrode 750 may not be formed in an edge portion of the second display substrate 700 to expose the overcoating layer 740.

The first display substrate 500 and the second display substrate 700 are placed to face each other with a predetermined cell gap therebetween. The liquid crystal layer 600 may be interposed between the first display substrate 500 and the second display substrate 700. An alignment layer may be formed on a surface of at least one of the first display substrate 600 and the second display substrate 700 which contact the liquid crystal layer 600. The pixel electrode 580 of the first display substrate 500 and the common electrode 750 of the second display substrate 700 may be placed to face each other to form an electric field in the liquid crystal layer 600.

As described above, the wire grid polarizer 10 uses metals, and it is highly efficient in reflecting light. Reflected light can be reflected again by the wire grid polarizer 10. By using the reflected light, the wire grid polarizer 10 may convert more light beams into light of one polarization. The wire grid polarizer 10 applied to the display device 1 may increase the transmission and polarization efficiency of light and improve the luminance of the display device 1.

By way of summation and review, to make polarized light, a film-type polarizer may be used in LCDs. The film-type polarizer may have a stacked structure of a tri-acetyl-cellulose (TAC) film and a polyvinyl alcohol (PVA) film, but properties of the film-type polarizer may be changed by high humidity and temperature. Accordingly, a nano wire grid polarizer having nano-sized metal patterns on a glass substrate may be considered as an alternative to the film-type polarizer. In a wire grid polarizer, non-uniform shapes of wire grid patterns may deteriorate polarization characteristics and undermine functions of the polarizer.

As described above, embodiments may provide a wire grid polarizer having thickness and edge uniformities of wire grid patterns improved by controlling the grain growth of a metal layer, and a display device including the wire grid polarizer.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A wire grid polarizer, comprising:
a substrate; and
a plurality of wire grid patterns arranged on the substrate at regular intervals, each of the wire grid patterns including a plurality of metal patterns in a stack on the substrate with an intermediate pattern interleaved between adjacent metal patterns in the stack.

2. The wire grid polarizer as claimed in claim 1, wherein each of the wire grid patterns includes:
a first metal pattern which is disposed on the substrate;
a first intermediate pattern which is disposed on the first metal pattern;
a second metal pattern which is disposed on the first intermediate pattern and whose grain growth is controlled by the first intermediate pattern;
a second intermediate pattern which is disposed on the second metal pattern;
a third metal pattern which is disposed on the second intermediate pattern and whose grain growth is controlled by the second intermediate pattern;
a third intermediate pattern which is disposed on the third metal pattern; and
a fourth metal pattern which is disposed on the third intermediate pattern and whose grain growth is controlled by the third intermediate pattern.

3. The wire grid polarizer as claimed in claim 1, wherein each of the wire grid patterns has a height of 150 to 250 nm.

4. The wire grid polarizer as claimed in claim 1, wherein each of the metal patterns has a height of 30 to 70 nm.

5. The wire grid polarizer as claimed in claim 1, wherein each of the metal patterns is made of one or more of aluminum (Al), gold (Au), silver (Ag), copper (Cu), chromium (Cr), iron (Fe), nickel (Ni), or a compound thereof.

6. The wire grid polarizer as claimed in claim 1, wherein each of the intermediate patterns is an oxide of the metal pattern disposed thereunder.

7. The wire grid polarizer as claimed in claim 1, wherein the wire grid patterns are spaced apart from one another in a first direction, the intervals having a pitch of 70 to 120 nm in the first direction.

8. The wire grid polarizer as claimed in claim 7, wherein the intermediate patterns, each being an oxide of the metal pattern disposed thereunder, have a thickness of 0.1 to 5 nm.

9. The wire grid polarizer as claimed in claim 7, wherein each of the wire grid patterns includes a first film pattern which is disposed on side surfaces the wire grid pattern and a second film pattern which is disposed on a top surface of the wire grid pattern.

10. The wire grid polarizer as claimed in claim 9, wherein each of the first film pattern and the second film pattern has a thickness of 3 to 8 nm.

11. The wire grid polarizer as claimed in claim 1, wherein the intermediate patterns are made of a different metal from the metal patterns.

12. The wire grid polarizer as claimed in claim 11, wherein:
each of the metal patterns is made of one or more of aluminum (Al), gold (Au), silver (Ag), copper (Cu), chromium (Cr), iron (Fe), nickel (Ni), or a compound thereof, and
each of the intermediate patterns is made of one or more of titanium (Ti), cobalt (Co), molybdenum (Mo), niobium (Nb), hafnium (Hf), palladium (Pd), platinum (Pt), rhodium (Rh), tantalum (Ta), or a compound thereof.

13. The wire grid polarizer as claimed in claim 10, wherein each of the wire grid patterns includes:
a first film pattern which is disposed on side surfaces of the metal patterns;
a second film pattern which is disposed on the top surface of the wire grid pattern; and
a third film pattern which is disposed on side surfaces of the intermediate patterns.

14. The wire grid polarizer as claimed in claim 13, wherein each of the first film pattern, the second film pattern, and the third film pattern has a thickness of 3 to 8 nm.

15. The wire grid polarizer as claimed in claim 13, wherein the first film pattern and the third film pattern are disposed alternately on side surfaces of each of the wire grid patterns.

16. The wire grid polarizer as claimed in claim 2, further comprising a capping pattern disposed on the fourth metal pattern, the capping pattern being made of: a metal different from the fourth metal pattern, or an oxide of the fourth metal pattern.

17. The wire grid polarizer as claimed in claim 16, wherein the capping pattern has a thickness of 5 to 10 nm.

18. The wire grid polarizer as claimed in claim 1, further comprising a buffer pattern between the metal patterns and the substrate.

19. A display device comprising the wire grid polarizer as claimed in claim 1.

20. A display device, comprising:
a protective layer which is disposed on a wire grid polarizer;
a gate line which is formed on the protective layer and extends in a first direction;
a data line which is insulated from the gate line and extends in a second direction;
a thin-film transistor (TFT) which is electrically connected to the gate line and the data line; and
a pixel electrode which is electrically connected to the TFT,
wherein the wire grid polarizer includes a substrate and a plurality of wire grid patterns on a substrate, the wire grid patterns being arranged on the substrate at regular intervals, each of the wire grid patterns including a plurality of metal patterns in a stack on the substrate with an intermediate pattern interleaved between adjacent metal patterns in the stack.
